(19) United States
(12) Patent Application Publication
(10) Pub. No.: US 2016/0035425 A1
(43) Pub. Date: Feb. 4, 2016

(54) MEMORY DEVICE AND PROGRAMMING METHOD THEREOF

(71) Applicant: MACRONIX International Co., Ltd., Hsinchu (TW)

(72) Inventors: Ping-Hung Tsai, Hsinchu (TW); Wen-Jer Tsai, Hsinchu (TW)

(21) Appl. No.: 14/447,208

(22) Filed: Jul. 30, 2014

(51) Int. Cl. G11C 16/10; G11C 16/04

(52) U.S. Cl. CPC G11C 16/10; G11C 16/0483

(57) ABSTRACT

A programming method for a memory device is provided. The memory device includes a first transistor, a memory cell string, and a second transistor which are electrically connected in series. The memory cell string includes a target memory cell, first and second peripheral memory cells adjacent to the target memory cell, and a plurality of non-target memory cells which are not adjacent to the target memory cell. The programming method includes following steps. The first transistor is turned on, and the second transistor is turned off. A pass voltage is applied to turn on the non-target memory cells, and an assistant voltage is applied to turn on the first and second peripheral memory cells. A programming voltage is applied to program the target memory cell. The assistant voltage is greater than the pass voltage and is less than the programming voltage.

### FIELD OF THE INVENTION

The invention relates to a memory device and a programming method thereof; more particularly, the invention relates to a planar memory device and a programming method thereof.

### DESCRIPTION OF RELATED ART

There are various non-volatile memories among which the flash memory is one of the mainstream products. An existing flash memory generally employs a non-planar structure to increase the gate-coupling ratio (GCR). Besides, with the gradual reduction of the size of memory cells, the flash memory may need to employ a planar structure. However, the gate-coupling ratio of the planar flash memory is relatively low. As a result, if the existing programming method is applied to the planar flash memory, the programming speed of the planar flash memory is often reduced significantly.

### SUMMARY OF THE INVENTION

The invention is directed to a memory device and a programming method thereof for increasing the programming speed of the memory device.

In an embodiment of the invention, a programming method for a memory device is provided. The memory array includes a first transistor, a memory cell string, and a second transistor electrically connected in series. The memory cell string includes a target memory cell, a first peripheral memory cell, a second peripheral memory cell, and a plurality of non-target memory cells. The first peripheral memory cell and the second peripheral memory cell are adjacent to the target memory cell, and the non-target memory cells are not adjacent to the target memory cell. The first transistor is turned on, and the second transistor is turned off. The non-target memory cells are turned on by applying a pass voltage, and the first and second peripheral memory cells are turned on by applying an assistant voltage. The target memory cell is programmed by applying a programming voltage. The assistant voltage is greater than the pass voltage and is less than the programming voltage.

In an embodiment of the invention, a memory device that includes a memory array and a circuit is provided. The memory arrayincludes a first transistor, a memory cell string, and a second transistor that are electrically connected in series. The memory cell string includes a target memory cell, a first peripheral memory cell, a second peripheral memory cell, and a plurality of non-target memory cells. The first peripheral memory cell and the second peripheral memory cell are adjacent to the target memory cell, and the non-target memory cells are not adjacent to the target memory cell. The circuit is electrically connected to the memory array. During a programming period, the circuit turns on the first transistor and turns off the second transistor. The circuit further turns on the non-target memory cells by applying a pass voltage and turns on the first peripheral memory cell and the second peripheral memory cell by applying an assistant voltage. The circuit also programs the target memory cell by applying a programming voltage. The assistant voltage is greater than the pass voltage and is less than the programming voltage.

In view of the above, the first and second peripheral memory cells adjacent to the target memory cell are turned on by applying the assistant voltage according to an embodiment of the invention. The assistant voltage is greater than the pass voltage and is less than the programming voltage. Thereby, the assistant voltage may speed up a rising speed of the voltage on the floating gate of the target memory cell and further increase the programming speed of the memory device.

Several exemplary embodiments accompanied with figures are described in detail below to further describe the invention in details.

### BRIEF DESCRIPTION OF THE DRAWINGS

FIG. 1 is a schematic view illustrating a memory device according to an embodiment of the invention.

FIG. 2 is a flowchart illustrating a programming method of a memory device according to an embodiment of the invention.

FIG. 3 is a schematic cross-sectional view illustrating a layout of a memory array according to an embodiment of the invention.

FIG. 4 is a flowchart illustrating details of steps S220 and S230 according to an embodiment of the invention.

FIG. 5 is a waveform diagram illustrating the embodiment depicted in FIG. 4.

FIG. 6 is a flowchart illustrating details of steps S220 and S230 according to another embodiment of the invention.

FIG. 7 is a waveform diagram illustrating the embodiment depicted in FIG. 6.

FIG. 8 is a curve diagram illustrating a programming voltage and a variation in a threshold voltage of a target memory cell according to an embodiment of the invention.

FIG. 9 is a flowchart illustrating details of steps S220 and S230 according to another embodiment of the invention.

FIG. 10 is a waveform diagram illustrating the embodiment depicted in FIG. 9.

FIG. 11 is a flowchart illustrating details of steps S220 and S230 according to another embodiment of the invention.

FIG. 12 is a waveform diagram illustrating the embodiment depicted in FIG. 11.

FIG. 13 is a curve diagram illustrating variations in a programming voltage and a threshold voltage of a target memory cell according to another embodiment of the invention.

### DETAILED DESCRIPTION OF DISCLOSED EMBODIMENTS

Before a programming method of a memory device is described, descriptions of the structure of the memory device are provided below.

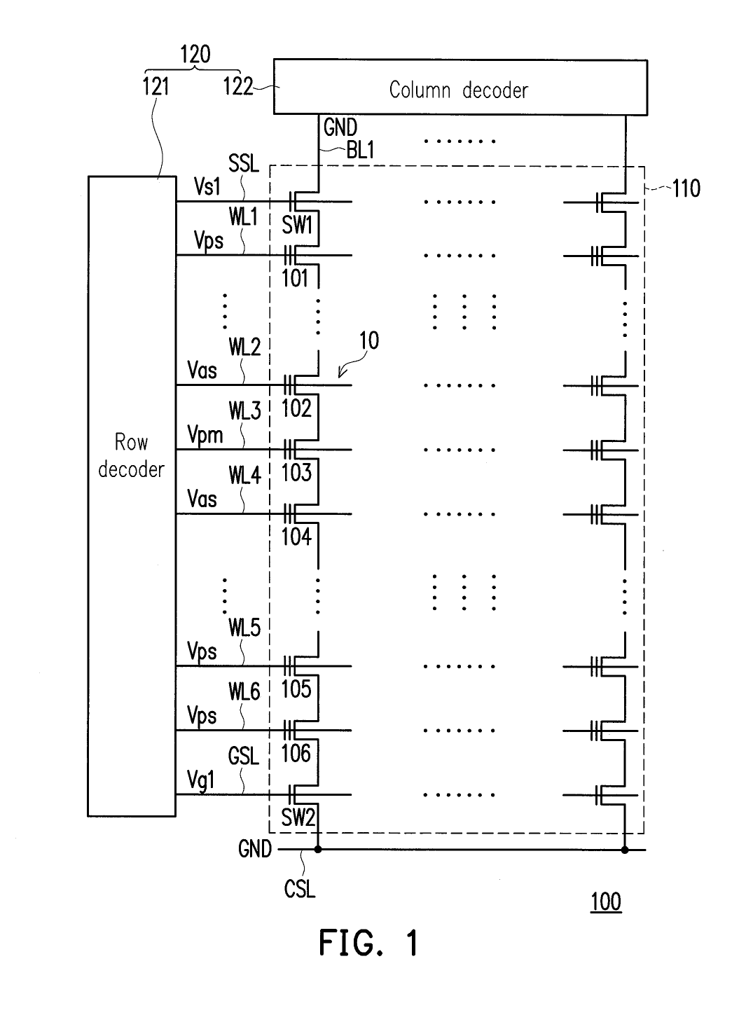

FIG. 1 is a schematic view illustrating a memory device according to an embodiment of the invention. With reference to FIG. 1, a memory device 100 includes a memory array 110 and a circuit 120. The circuit 120 includes a row decoder 121 and a column decoder 122, and the memory array 110 includes a plurality of first transistors, a plurality of memory cell strings, and a plurality of second transistors which are electrically connected in series. For instance, the memory array 110 includes the first transistor SW1, the memory cell string 10, and the second transistor SW2. The first transistor SW1, the memory cell string 10, and the second transistor SW2 are serially connected between a bit line BL1 and a common source line CSL. The memory cell string 10 comprises a plurality of memory cells 101 to 106 that are serially connected.

The row decoder 121 is electrically connected to each of the first transistors (e.g., the first transistor SW1) in the memory array 110 through a string selection line SSL. Besides, the row decoder 121 is electrically connected to each of the second transistors (e.g., the second transistor SW2) in the memory array 110 through a ground selection line GSL. The row decoder 121 is electrically connected to the memory cells (e.g., the memory cells 101 to 106) in the memory array 110 through word lines WL1 to WL6. The column decoder 122 is electrically connected to the memory array 110 through a plurality of bit lines (e.g., the bit line BL1).

During operation, the row decoder 121 and the column decoder 122 in the circuit 120 provide corresponding voltages to the memory array 110 according to address data, so as to program at least one memory cell in the memory array 110. For instance, the memory array 100 may program the memory cell 103 in the memory cell string 10. Besides, while the memory cell 103 is programmed, the memory cell 103 is regarded as the target memory cell, two memory cells 102 and 104 adjacent to the memory cell 103 are regarded as the first peripheral memory cell and the second peripheral memory cell, and the memory cells 101, 105, and 106 that are not adjacent to the memory cell 103 are regarded as to the non-target memory cells.

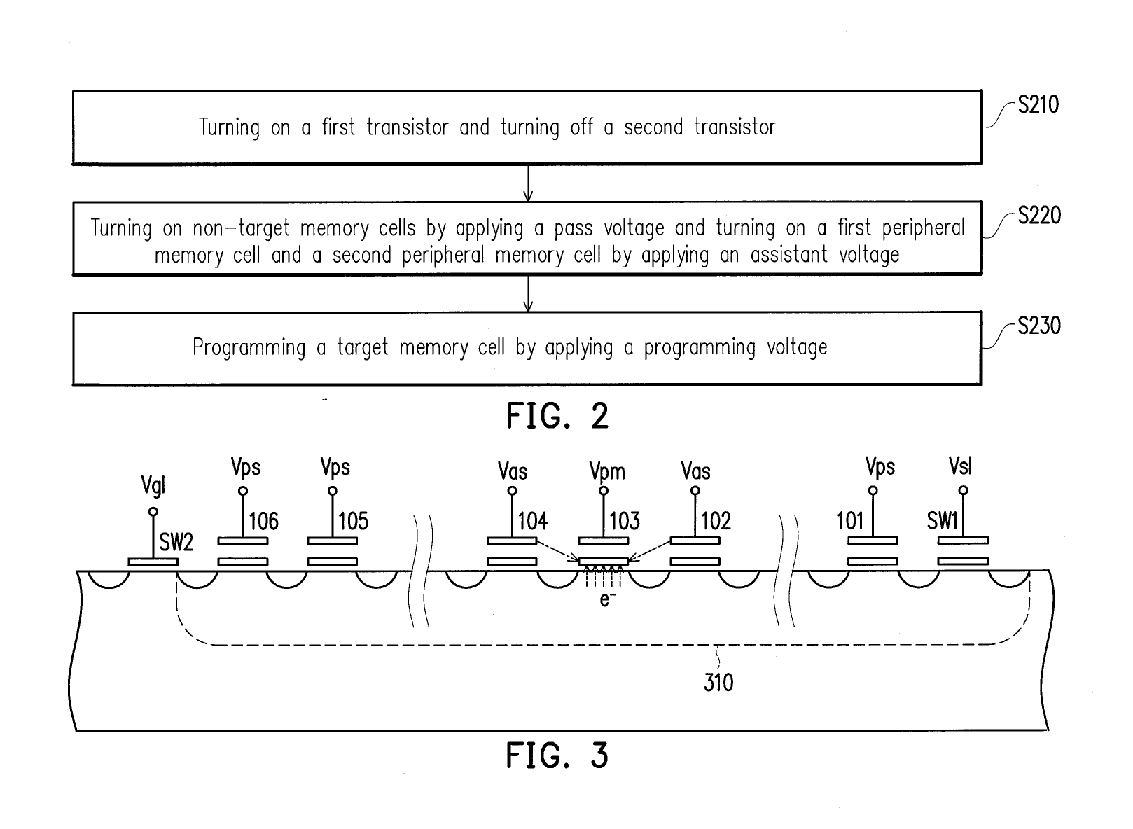

In order for people having ordinary skill in the art to comprehend the present embodiment to a great extent, FIG. 2 that is a flowchart illustrating a programming method of a memory device according to an embodiment of the invention is provided, and the programming operation of the target memory cell 103 is further explained hereinafter with reference to FIG. 1 and FIG. 2.

In step S210, during a programming period, the circuit 120 turns on the first transistor SW1 and turns off the second transistor SW2. For instance, the column decoder 122 provides a ground voltage GND to the bit line BL1 electrically connected to the memory cell string 10, and the level of the common source line CSL is maintained at the ground voltage GND. The row decoder 121 provides a selection voltage Vs1 to the string selection line SSL electrically connected to the first transistor SW1 and provides a selection voltage Vg1 to the ground selection line GSL electrically connected to the second transistor SW2. In step S220, during the programming period, the circuit 120 further turns on the non-target memory cells 101, 105, and 106 by applying a pass voltage Vps and turns on the first peripheral memory cell 102 and the second peripheral memory cell 104 by applying an assistant voltage Vas. In step S230, during the programming period, the circuit 120 programs the target memory cell 103 by applying a programming voltage Vpm.

FIG. 3 is a schematic cross-sectional view illustrating a layout of a memory array according to an embodiment of the invention. As shown in FIG. 3, since the first transistor SW1 is turned on, and the second transistor SW2 is turned off, one end of the memory cell string 10 is maintained at the ground voltage GND, and the other end of the memory cell string 10 is floating. Besides, the memory cell string 10 may form a channel 310 in response to the voltage provided by the circuit 120.

The programming voltage Vpm applied to the target memory cell 103 may be coupled to the floating gate of the target memory cell 103. Therefore, the amount of the programming voltage Vpm coupled to the floating gate of the target memory cell 103 is sufficient to generate a large electric field across the oxide layer of the target memory cell 103, thus inducing the electrons in the channel 310 to be injected into the floating gate of the target memory cell 103 in a Fowler-Nordheim (FN) tunneling manner.

Note that the assistant voltage Vas applied to the two peripheral memory cells 102 and 104 may also be coupled to the floating gate of the target memory cell 103. Besides, the amount of the assistant voltage Vas coupled to the floating gate of the target memory cell 103 may raise the voltage on the floating gate of the target memory cell 103 and assist the electrons in the channel 310 to be injected quickly into the floating gate of the target memory cell 103, thus increasing the programming speed of the target memory cell 103. Accordingly, it may be prevented to significantly reduce the programming speed of the memory cell caused by the lower gate-coupling ratio. In other words, the programming method illustrated in FIG. 2 not only can be applied to the memory array 110 with a non-planar structure but also can be applied to the memory array 110 with a planar structure. Namely, the memory array 110 in one embodiment may employ a planar structure so as to reduce the size of the memory device 100.

For instance, a parasitic capacitance may be generated between the control gate of the first peripheral memory cell 102 and the floating gate of the target memory cell 103, and thereby the assistant voltage Vas applied to the first peripheral memory cell 102 may be coupled to the floating gate of the target memory cell 103. Similarly, another parasitic capacitance may be generated between the control gate of the second peripheral memory cell 104 and the floating gate of the target memory cell 103, and thereby the assistant voltage Vas applied to the second peripheral memory cell 104 may be also coupled to the floating gate of the target memory cell 103.

Besides, the assistant voltage Vas is greater than the pass voltage Vps; therefore, the assistant voltage Vas turns on the two peripheral memory cells 102 and 104, and the amount of the assistant voltage Vas coupled to the floating gate of the target memory cell 103 may increase the speed of the electrons in the channel 310 to be injected into the floating gate of the target memory cell 103. Accordingly, the assistant voltage Vas may speed up a rising speed of the voltage on the floating gate of the target memory cell 103 and further increase the programming speed of the memory device 100. In addition, the assistant voltage Vas provided by the circuit 120 is less than the lowest level of the programming voltage Vpm (i.e., the minimum programming voltage), so as to prevent the two peripheral memory cells 102 and 104 from being programmed by the assistant voltage Vas.

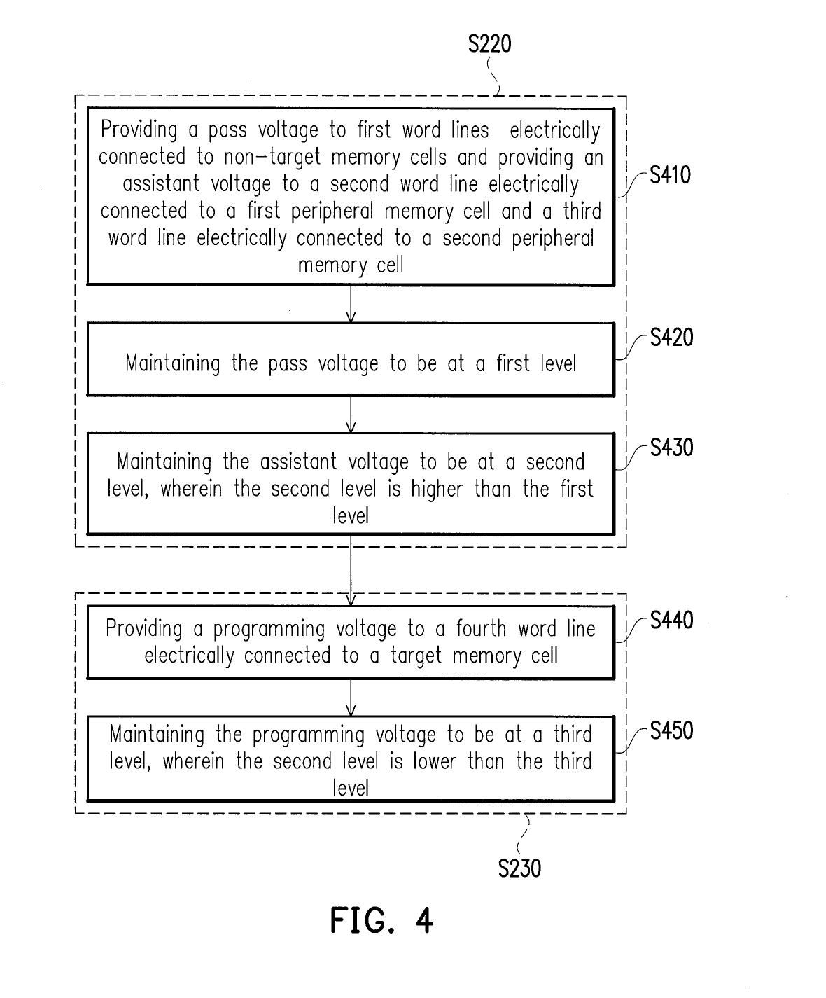

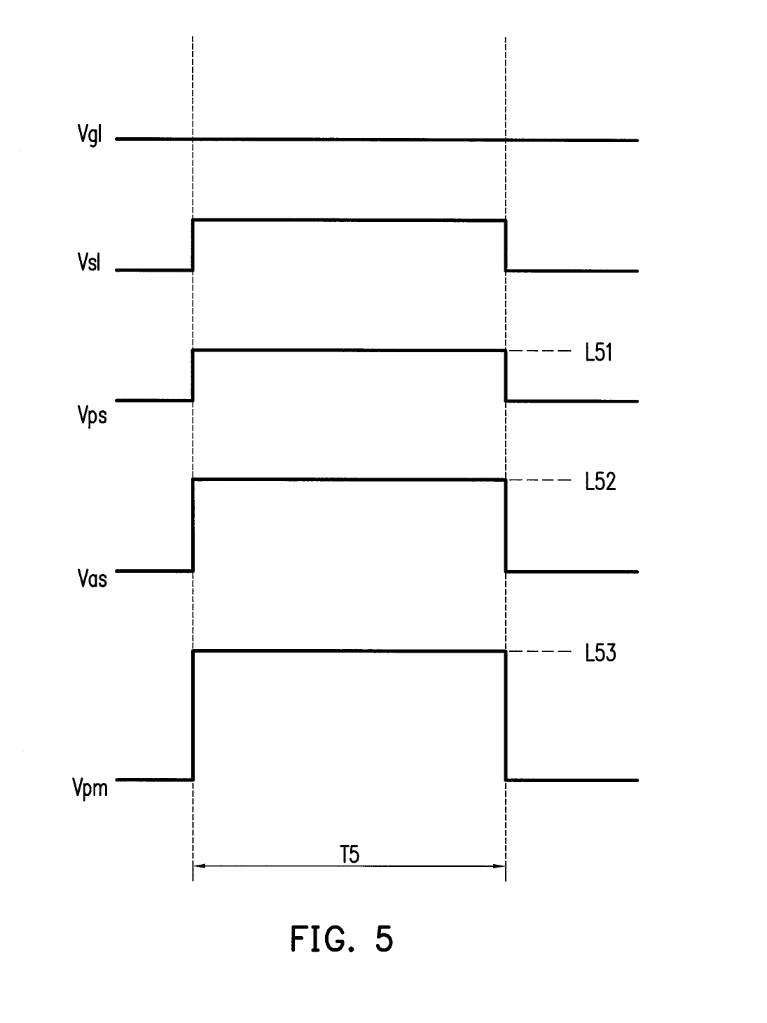

FIG. 4 is a flowchart illustrating details of steps S220 and S230 according to an embodiment of the invention. FIG. 5 is a waveform diagram illustrating the embodiment depicted in FIG. 4. The details of the programming operation of the memory device 100 are provided hereinafter with reference to FIG. 1, FIG. 4, and FIG. 5.

In case of turning on the memory cells, the row decoder 121 generates the selection voltage Vg1, the selection voltage Vs1, the pass voltage Vps, the assistant voltage Vas, and the programming voltage Vpm, and the selection voltage Vg1 is equal to the ground voltage GND. Besides, in step S410, the row decoder 121 in the programming period T5 provides the pass voltage Vps to the word lines WL1, WL5, and WL6 (i.e., the first word lines) electrically connected to the non-target memory cells 101, 105, and 106. The row decoder 121 also provides the assistant voltage Vas to the word line WL2 (i.e., the second word line) electrically connected to the first peripheral memory cell 102 and the word line WL4 (i.e., the third word line) electrically connected to the second peripheral memory cell 104. In step S420 and step S430, the row decoder 121 in the programming period T5 maintains the pass voltage Vps to be at the first level L51 and maintains the assistant voltage Vas to be at the second level L52.

As to the target memory cell 103, in step S440 and step S450, the row decoder 121 provides the programming voltage Vpm to the word line WL3 (e.g., the fourth word line) electrically connected to the target memory cell 103 and maintains the programming voltage Vpm to be at the third level L53. Thereby, the memory device 100 is able to program the target memory cell 103. Note that the second level L52 is higher than the first level L51, such that the assistant voltage Vas may not only turn on the two peripheral memory cells 102 and 104 but also speed up the rising speed of the voltage on the floating gate of the target memory cell 103. Moreover, the second level L52 is lower than the third level L53 (i.e., the minimum programming voltage), so as to prevent the two peripheral memory cells 102 and 104 from being programmed by the assistant voltage Vas (i.e., the program disturbance).

According to the embodiments shown in FIG. 4 and FIG. 5, respectively, the levels of the assistant voltage Vas and the programming voltage Vpm remain constant; however, the invention is not limited thereto. For instance, in another embodiment of the invention, one of the assistant voltage Vas and the programming voltage Vpm may be raised in a stepwise manner, so as to further expedite the programming speed of the memory device 100.

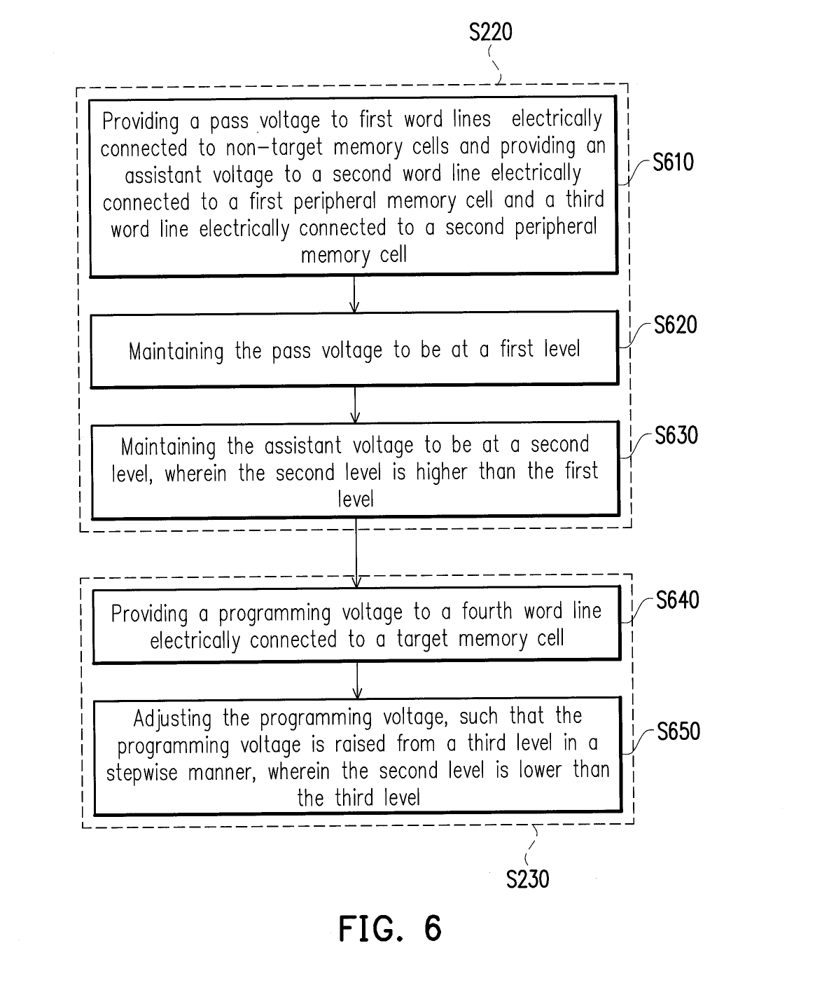

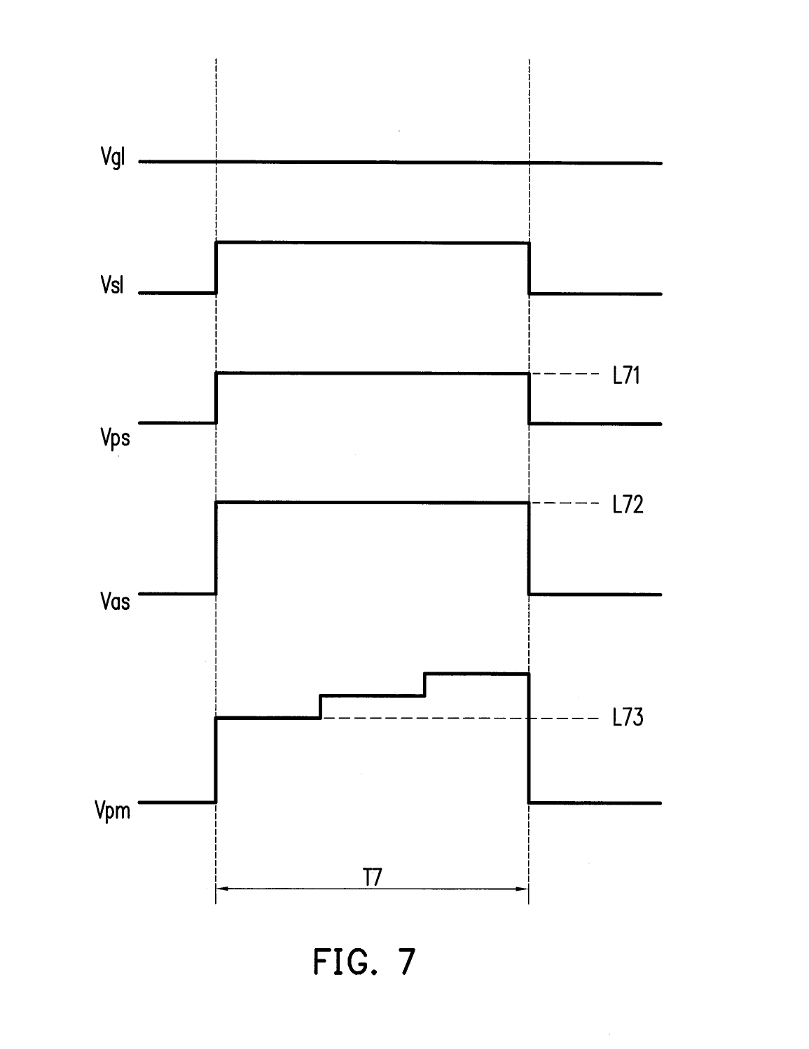

FIG. 6 is a flowchart illustrating details of steps S220 and S230 according to another embodiment of the invention. FIG. 7 is a waveform diagram illustrating the embodiment depicted in FIG. 6. According to the embodiment shown in FIG. 6, the level of the assistant voltage Vas remains constant, while the level of the programming voltage Vpm is adjusted in a stepwise manner.

Specifically, steps S610 to S630 depicted in FIG. 6 are similar to the steps S410 to S430 illustrated in FIG. 4. For instance, in the programming period T7, the row decoder 121 provides the pass voltage Vps to the word lines WL1, WL5, and WL6 and provides the assistant voltage Vas to the word lines WL2 and WL4. Besides, the row decoder 121 maintains the pass voltage Vps to be at the first level L71 and maintains the assistant voltage Vas to be at the second level L72. Thereby, the non-target memory cells 101, 105, and 106 and the two peripheral memory cells 102 and 104 can be turned on.

In step S640, during the programming period T7, the row decoder 121 provides the programming voltage Vpm to the word lines WL3. In step S650, during the programming period T7, the row decoder 121 adjusts the programming voltage Vpm, such that the programming voltage Vpm is raised from the third level L73 in a stepwise manner. Thereby, the memory device 100 is able to program the target memory cell 103. Note that the second level L72 is lower than the third level L73 (i.e., the minimum programming voltage), so as to prevent the two peripheral memory cells 102 and 104 from being programmed by the assistant voltage Vas (i.e., the program disturbance). Besides, the second level L72 is higher than the first level L71, such that the assistant voltage Vas may speed up the rising speed of the voltage on the floating gate of the target memory cell 103.

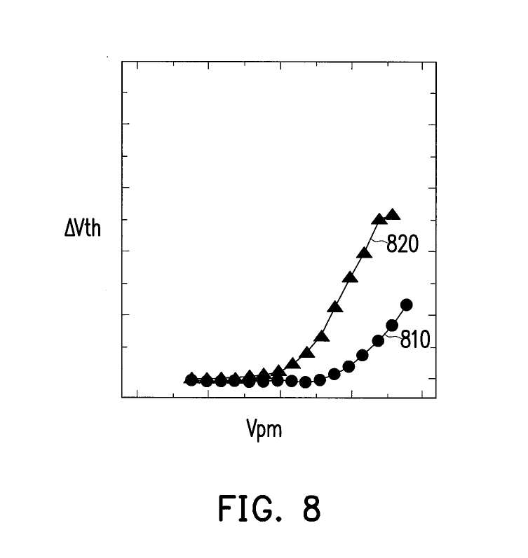

FIG. 8 is a curve diagram illustrating a programming voltage and a variation in a threshold voltage of a target memory cell according to an embodiment of the invention. In the embodiment shown in FIG. 8, the memory array 110 is a planar NAND memory array, and the curve 810 represents the variation in the threshold voltage, given that the incremental step pulse programming (ISPP) method is adopted in the planar NAND memory array; the curve 820 represents the variation in the threshold voltage, given that the programming method depicted in FIG. 6 is adopted in the planar NAND memory array. According to the result of comparing the curve 810 with the curve 820, the variation of the threshold voltage in response to the unit increment in the programming voltage may be significantly raised if the programming method depicted in FIG. 6 is adopted, which is conducive to an increase in the programming speed of the memory device 100.

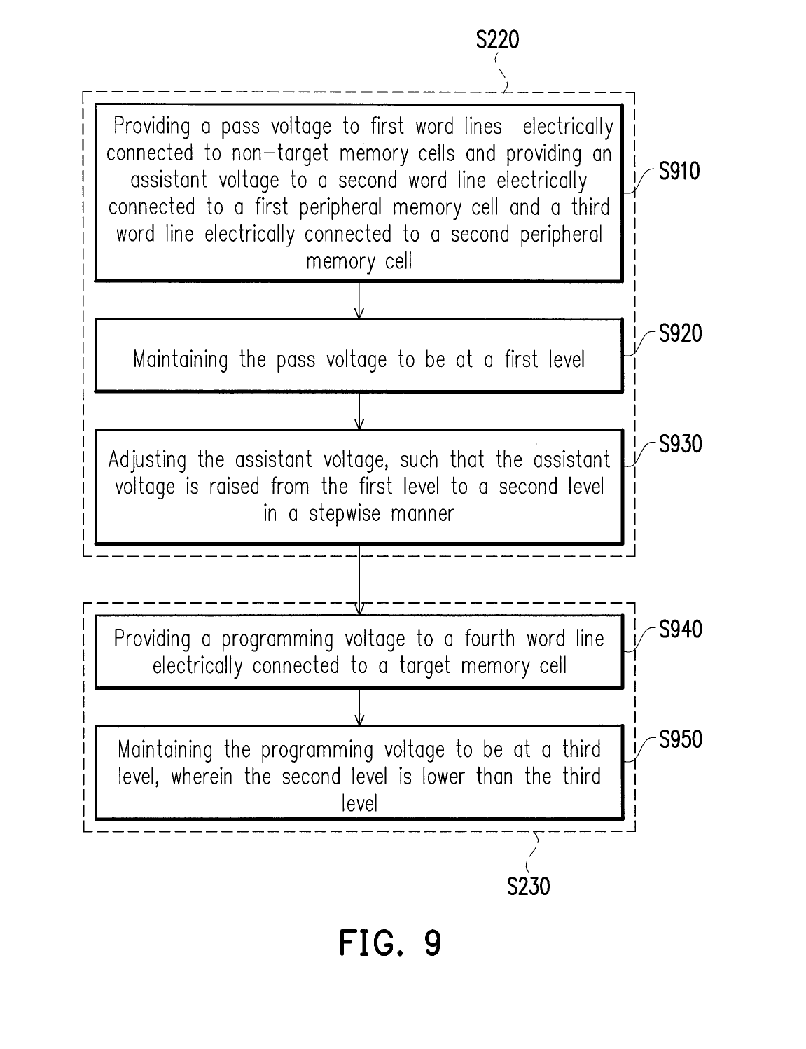

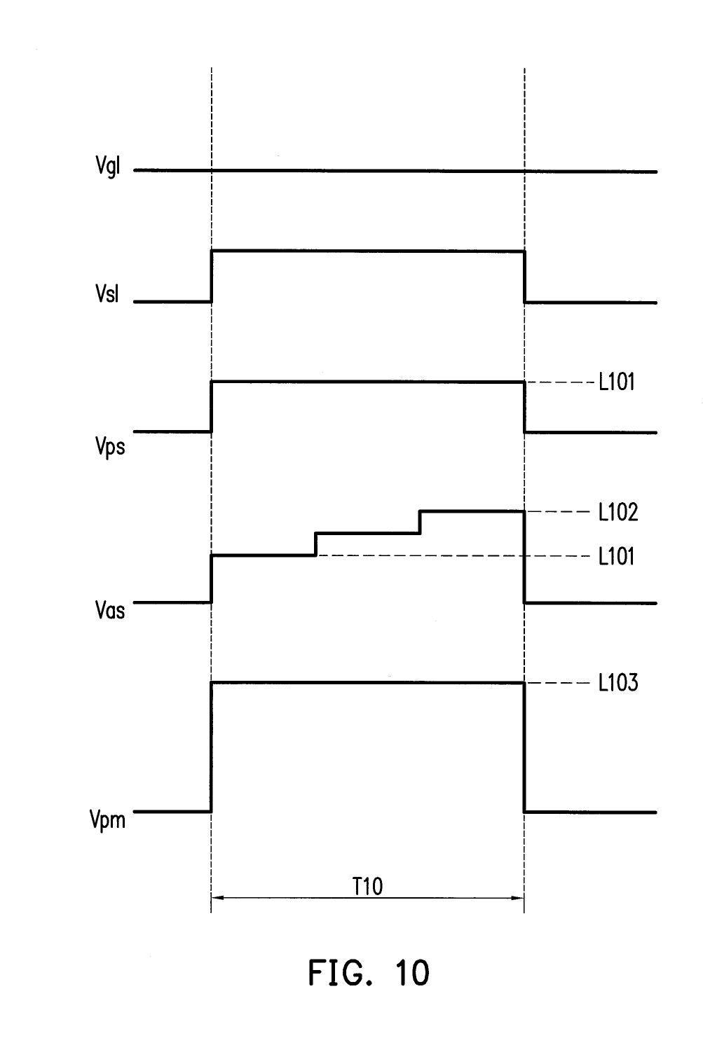

FIG. 9 is a flowchart illustrating details of steps S220 and S230 according to another embodiment of the invention, and FIG. 10 is a waveform diagram illustrating the embodiment depicted in FIG. 9. According to the embodiment shown in FIG. 9, the level of the programming voltage Vpm remains constant, while the level of the assistant voltage Vas is adjusted in a stepwise manner.

In step S910, during the programming period T10, the row decoder 121 provides the pass voltage Vps to the word lines WL1, WL5, and WL6 and provides the assistant voltage Vas to the word lines WL2 and WL4. In step S920, during the programming period T10, the row decoder 121 maintains the pass voltage Vps to be at the first level L101. In step S930, during the programming period T10, the row decoder 121 adjusts the assistant voltage Vas, such that the assistant voltage Vas is raised from the first level L101 to the second level L102 in a stepwise manner.

Specifically, steps S940 to S950 depicted in FIG. 9 are similar to the steps S440 to S450 illustrated in FIG. 4. For instance, in the programming period T10, the row decoder 121 provides the programming voltage Vpm to the word line WL3 and maintains the programming voltage Vpm to be at the third level L103. Thereby, the memory device 100 is able to program the target memory cell 103. Note that the assistant voltage Vas may not only turn on the two peripheral memory cells 102 and 104 but also speed up the rising speed of the voltage on the floating gate of the target memory cell 103. Moreover, the second level L102 is lower than the third level L103 (i.e., the minimum programming voltage), so as to prevent the two peripheral memory cells 102 and 104 from being programmed by the assistant voltage Vas (i.e., the program disturbance).

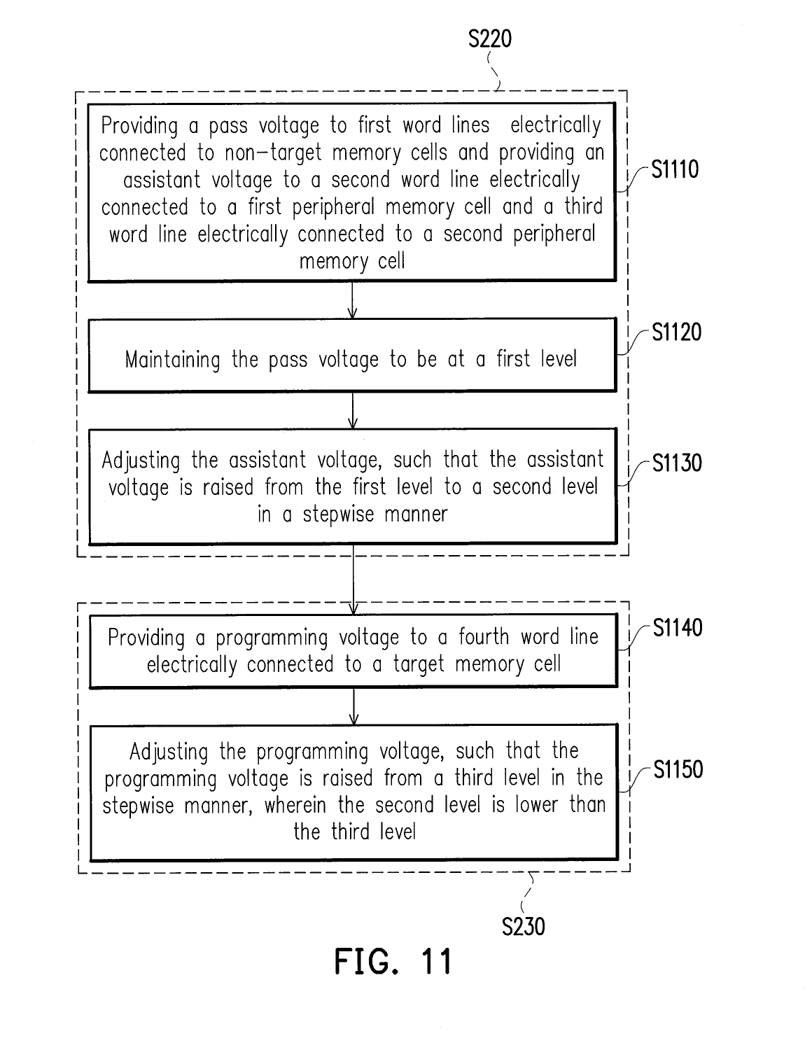

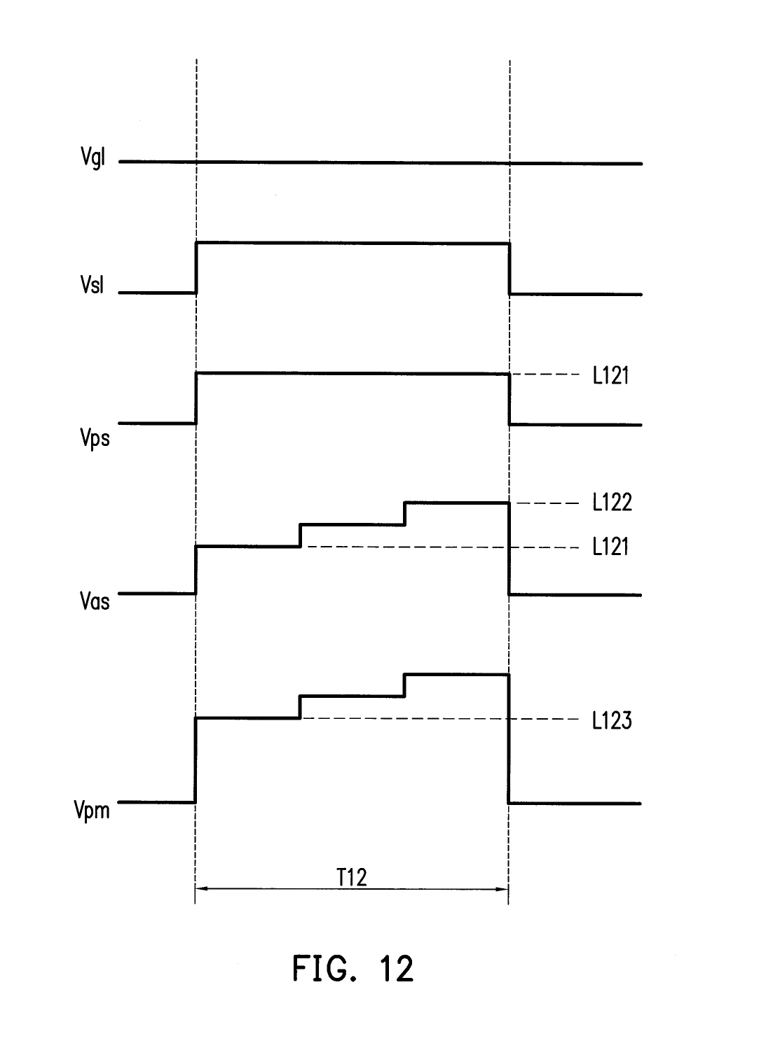

FIG. 11 is a flowchart illustrating details of steps S220 and S230 according to another embodiment of the invention, and FIG. 12 is a waveform diagram illustrating the embodiment depicted in FIG. 11. According to the embodiment shown in FIG. 11, the level of the assistant voltage Vas and the level of the programming voltage Vpm are adjusted in a stepwise manner.

Specifically, steps S1110 to S1130 depicted in FIG. 11 are similar to the steps S910 to S930 illustrated in FIG. 9. For instance, in the programming period T12, the row decoder 121 provides the pass voltage Vps to the word lines WL1, WL5, and WL6 and provides the assistant voltage Vas to the word lines WL2 and WL4. Besides, the row decoder 121 maintains the pass voltage Vps to be at the first level L121 and adjusts the assistant voltage Vas to be raised from the first level L121 to the second level L122 in a stepwise manner.

Specifically, steps S1140 to S1150 depicted in FIG. 11 are similar to the steps S640 to S650 illustrated in FIG. 6. For instance, in the programming period T12, the row decoder 121 provides the programming voltage Vpm to the word lines WL3. Besides, the row decoder 121 adjusts the programming voltage Vpm, such that the programming voltage Vpm is raised from the third level L123 in the stepwise manner. Thereby, the memory device 100 is able to program the target memory cell 103. Note that the second level L122 is lower than the third level L123 (i.e., the minimum programming voltage), so as to prevent the two peripheral memory cells 102 and 104 from being programmed by the assistant voltage Vas (i.e., the program disturbance). Additionally, the assistant voltage Vas may not only turn on the two peripheral memory cells 102 and 104 but also speed up the rising speed of the voltage on the floating gate of the target memory cell 103.

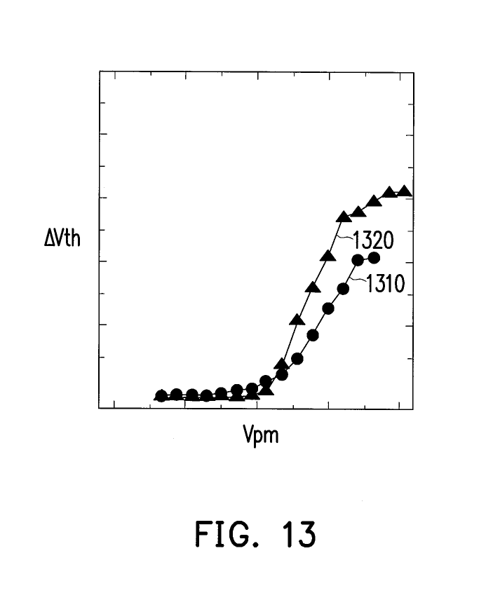

In comparison with the assistant voltage Vas having the constant level, as shown in FIG. 6, the assistant voltage Vas that is raised in a stepwise manner may further increase the programming speed of the memory device 100. FIG. 13 is a curve diagram illustrating variations in a programming voltage and a threshold voltage of a target memory cell according to another embodiment of the invention. In the embodiment shown in FIG. 13, the memory array 110 is a planar NAND memory array, and the curve 1310 represents the variation in the threshold voltage, given that the programming method depicted in FIG. 6 is adopted in the planar NAND memory array; the curve 1320 represents the variations in the threshold voltage, given that the programming method depicted in FIG. 9 is adopted in the planar NAND memory array. According to the result of comparing the curve 1310 with the curve 1320, the assistant voltage Vas that is raised in a stepwise manner may further speed up the programming operation of the memory device 100.

To sum up, two peripheral memory cells adjacent to the target memory cell are turned on by applying the assistant voltage. The assistant voltage is greater than the pass voltage and is less than the programming voltage. Thereby, the assistant voltage not only turns on the two peripheral memory cells but also speeds up a rising speed of the voltage on the floating gate of the target memory cell and further increases the programming speed of the memory device.

Although the invention has been described with reference to the above embodiments, it will be apparent to one of ordinary skill in the art that modifications to the described embodiments may be made without departing from the spirit of the invention. Accordingly, the scope of the invention will be defined by the attached claims and not by the above detailed descriptions.

What is claimed is:

1. A programming method for a memory device, the memory device comprising a first transistor, a memory cell string, and a second transistor electrically connected in series, the memory cell string comprising a target memory cell, a first peripheral memory cell, a second peripheral memory cell, and a plurality of non-target memory cells, the first peripheral memory cell and the second peripheral memory cell being adjacent to the target memory cell, the non-target memory cells being not adjacent to the target memory cell, the programming method comprising:
turning on the first transistor and turning off the second transistor;
turning on the non-target memory cells by applying a pass voltage and turning on the first peripheral memory cell and the second peripheral memory cell by applying an assistant voltage; and
programming the target memory cell by applying a programming voltage, wherein the assistant voltage is greater than the pass voltage and is less than the programming voltage.

2. The programming method for the memory device as recited in claim 1, wherein the step of turning on the non-target memory cells by applying the pass voltage and turning on the first peripheral memory cell and the second peripheral memory cell by applying the assistant voltage comprises:
providing the pass voltage to a plurality of first word lines electrically connected to the non-target memory cells and providing the assistant voltage to a second word line electrically connected to the first peripheral memory cell and a third word line electrically connected to the second peripheral memory cell;
maintaining the pass voltage to be at a first level; and
maintaining the assistant voltage to be at a second level, the second level being higher than the first level.

3. The programming method for the memory device as recited in claim 2, wherein the step of programming the target memory cell by applying the programming voltage comprises:
providing the programming voltage to a fourth word line electrically connected to the target memory cell; and
maintaining the programming voltage to be at a third level, the second level being lower than the third level.

4. The programming method for the memory device as recited in claim 2, wherein the step of programming the target memory cell by applying the programming voltage comprises:
providing the programming voltage to a fourth word line electrically connected to the target memory cell; and
adjusting the programming voltage, such that the programming voltage is raised from a third level in a stepwise manner, the second level being lower than the third level.

5. The programming method for the memory device as recited in claim 1, wherein the step of turning on the non-target memory cells by applying the pass voltage and turning on the first peripheral memory cell and the second peripheral memory cell by applying the assistant voltage comprises:
providing the pass voltage to a plurality of first word lines electrically connected to the non-target memory cells and providing the assistant voltage to a second word line electrically connected to the first peripheral memory cell and a third word line electrically connected to the second peripheral memory cell;
maintaining the pass voltage to be at a first level; and
adjusting the assistant voltage, such that the assistant voltage is raised from the first level to a second level in a stepwise manner.

6. The programming method for the memory device as recited in claim 5, wherein the step of programming the target memory cell by applying the programming voltage comprises:
providing the programming voltage to a fourth word line electrically connected to the target memory cell; and
maintaining the programming voltage to be at a third level, the second level being lower than the third level.

7. The programming method for the memory device as recited in claim 5, wherein the step of programming the target memory cell by applying the programming voltage comprises:
providing the programming voltage to a fourth word line electrically connected to the target memory cell; and
adjusting the programming voltage, such that the programming voltage is raised from a third level in the stepwise manner, the second level being lower than the third level.

8. A memory device comprising:
a memory array comprising a first transistor, a memory cell string, and a second transistor electrically connected in series, the memory cell string comprising a target memory cell, a first peripheral memory cell, a second peripheral memory cell, and a plurality of non-target memory cells, the first peripheral memory cell and the second peripheral memory cell being adjacent to the target memory cell, the non-target memory cells being not adjacent to the target memory cell; and
a circuit electrically connected to the memory array, during a programming period, the circuit:
turning on the first transistor and turning off the second transistor;
turning on the non-target memory cells by applying a pass voltage and turning on the first peripheral memory cell and the second peripheral memory cell by applying an assistant voltage; and
programming the target memory cell by applying a programming voltage, wherein the assistant voltage is greater than the pass voltage and is less than the programming voltage.

9. The memory device as recited in claim 8, during the programming period, the circuit further:
maintaining the pass voltage to be at a first level;
maintaining the assistant voltage to be at a second level; and
adjusting the programming voltage, such that the programming voltage is raised from a third level in a stepwise manner, wherein the second level is higher than the first level and lower than the third level.

10. The memory device as recited in claim 8, during the programming period, the circuit further:
maintaining the pass voltage to be at a first level;
adjusting the assistant voltage, such that the assistant voltage is raised from the first level to a second level in a stepwise manner; and
adjusting the programming voltage, such that the programming voltage is raised from a third level in the stepwise manner, the second level being lower than the third level.
